(19) United States
(12) Patent Application Publication
(10) Pub. No.: US 2021/0225211 A1
(43) Pub. Date: Jul. 22, 2021

(54) DIGITAL DISPLAY

(71) Applicants: LITE-ON OPTO TECHNOLOGY (CHANGZHOU) CO., LTD., CHANGZHOU CITY (CN); LITE-ON TECHNOLOGY CORPORATION, TAIPEI CITY (TW)

(72) Inventors: CHIN-KUAN LIN, NEW TAIPEI CITY (TW); JU-LING CHENG, New Taipei City (TW); YI-CHU LIN, New Taipei City (TW)

(21) Appl. No.: 17/152,697

(22) Filed: Jan. 19, 2021

Related U.S. Application Data
(60) Provisional application No. 62/963,195, filed on Jan. 20, 2020.
(60) Provisional application No. 63/002,394, filed on Mar. 31, 2020.

(30) Foreign Application Priority Data
Dec. 15, 2020 (CN) 202011482093.8

(51) Int. Cl. G09F 9/302; G06F 1/18; H05K 5/00

(52) U.S. Cl. CPC G09F 9/3023; H05K 5/0017; G06F 1/181

(57) ABSTRACT

A digital display including a light unit, a display unit and a fixing unit is provided. The light unit is connected to the display unit, and the display unit and the fixing unit either are a single component or are each an independent component. The digital display can fix the display unit on an external substrate in an upright manner through the fixing unit.

### CROSS-REFERENCE TO RELATED PATENT APPLICATION

This application claims priority to the U.S. Provisional Patent Application Ser. No. 62/963,195 filed on Jan. 20, 2020, the U.S. Provisional Patent Application Ser. No. 63/002,394 filed on Mar. 31, 2020, and China Patent Application No. 202011482093.8, filed on Dec. 15, 2020 in People's Republic of China which applications are incorporated herein by reference in their entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a digital display, and more particularly to an upright digital display.

### BACKGROUND OF THE DISCLOSURE

With the rapid development of industry and technology, digital displays are widely used in electronic products to display information. Currently, most laminated digital displays that are disposed on a circuit board are flatly mounted thereon.

### SUMMARY OF THE DISCLOSURE

In response to the above-referenced technical inadequacies, the present disclosure provides a digital display capable of being disposed upright.

In one aspect, the present disclosure provides a digital display that includes a light unit, a display unit and a fixing unit. The light unit has a light emitting surface. The display unit has a display surface corresponding to the light emitting surface. The fixing unit is used to hold the display unit upright on an external substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings in which:

FIG. 1 is a first exploded view of a digital display according to a first embodiment of the present disclosure.

FIG. 2 is a second exploded view of the digital display according to the first embodiment of the present disclosure.

FIG. 3 is a partly exploded view of a digital display according to a second embodiment of the present disclosure.

FIG. 4 is a perspective view of a digital display according to a third embodiment of the present disclosure.

FIG. 5 is a side view of the digital display according to the third embodiment of the present disclosure.

FIG. 6 is an exploded view of a digital display according to a fourth embodiment of the present disclosure.

FIG. 7 is a side view of the digital display according to the fourth embodiment of the present disclosure.

FIG. 8 is a first exploded view of a digital display according to a fifth embodiment of the present disclosure.

FIG. 9 is a side view of the digital display according to the fifth embodiment of the present disclosure.

FIG. 10 is a second exploded view of the digital display according to the fifth embodiment of the present disclosure.

FIG. 11 is a schematic sectional view of part XI-XI in FIG. 10.

FIG. 12 is a third exploded view of the digital display according to the fifth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

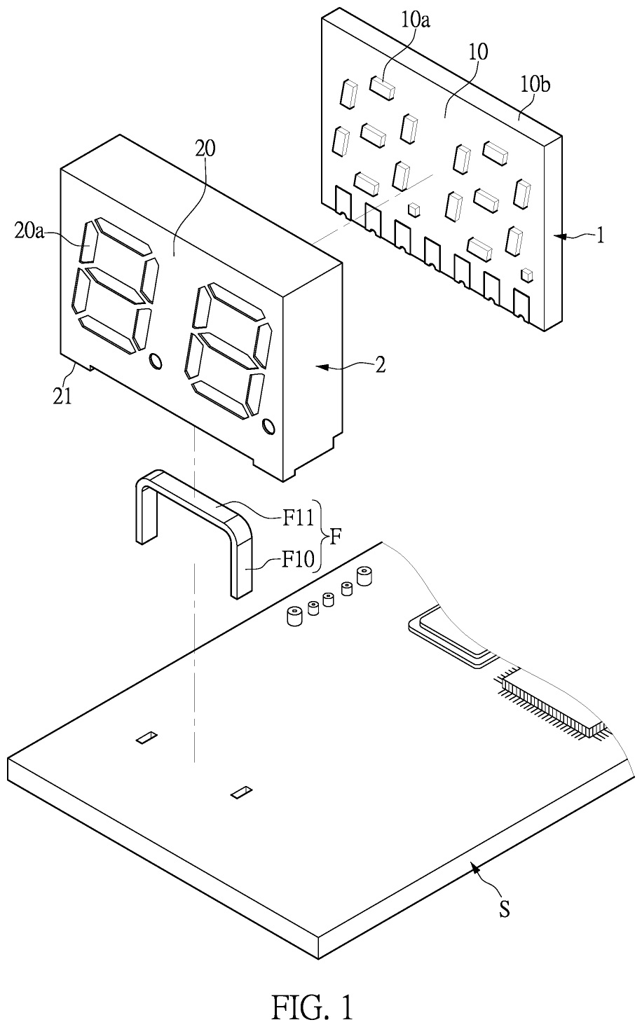

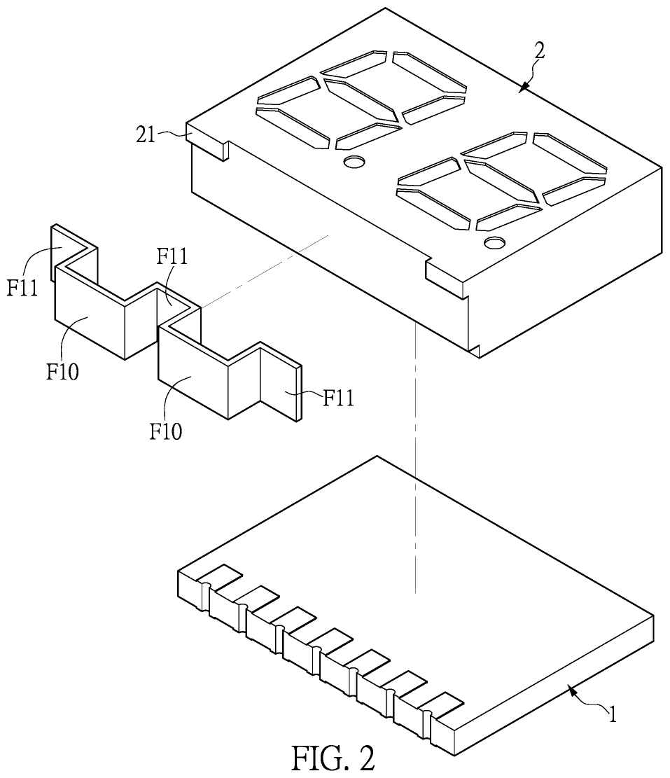

Reference is made to FIG. 1 and FIG. 2, in which a first exploded view and a second exploded view of a digital display according to a first embodiment of the present disclosure are shown, respectively. The first embodiment of the present disclosure provides a digital display Z including a light unit 1, a display unit 2 and a fixing unit F. The light unit 1 has a front 10 as a light emitting surface and a rear 11 opposite to the front 10 as an electrical connection part. The display unit 2 has a display surface 20 corresponding to the front 10. The fixing unit F is used to hold the display unit 2 upright on an external substrate S.

Specifically, as shown in FIG. 1, the digital display Z of the present disclosure includes the light unit 1, the display unit 2 and the fixing unit F. The light unit 1 can be a substrate with a plurality of optoelectronics (such as a light emitting diode (LED) device including LED chip and LED package). The front 10 of the light unit 1 can be connected to the display unit 2. The display unit 2 cooperates with a light beam generated by the front 10 of the light unit 1 to display digits, text, symbols and graphics on the display surface 20. The fixing unit F can be disposed at a bottom of the display unit 2. Accordingly, the digital display Z of the present disclosure can be connected to the external substrate S by the fixing unit F, so that the fixing unit F can hold the display unit 2 upright on the external substrate S. In addition, the light unit 1 can also be electrically connected to the external substrate S. The external substrate S can be a circuit board, but is not limited thereto.

Further, the display unit 2 has a plurality of display windows 20a that are hollow through the front 10 to the display surface 20, and the display windows 20a cooperate to form the displayed digits, text, symbols and graphics. In addition, the display unit 2 can include a reflective member and a print tape pasted onto the reflective member, wherein the print tape has a plurality of light transmissive segments that can be formed as the plurality of display windows 20a. The light unit 1 can include a plurality of optoelectronics 10a corresponding to each of the display windows 20a and a circuit substrate 10b, and the plurality of optoelectronics 10a can be disposed on the front 10 of the circuit substrate 10b. In the present embodiment, the digital display Z of the present disclosure has two numbers, each of which has eight display windows 20a. Seven of the display windows 20a form an “8” shaped display character, and another one of the display windows 20a is a decimal point display character at a lower right corner of the “8” shaped display character, but the present disclosure is not limited thereto.

In an exemplary embodiment, the display unit 2 and the fixing unit F of the present disclosure can be an integrated component. For example, the fixing unit F can be made of metal or plastic, and the fixing unit F can be made in advance. Then, during the process of forming the display unit 2, a part of the fixing unit F is placed into the display unit 2. After the display unit 2 is formed, the display unit 2 and the fixing unit F can be a single, integral component.

Further, the fixing unit F can include a plurality of first fixing parts F10 and at least one supporting part F11 correspondingly embedded in the display unit 2, and the plurality of first fixing parts F10 are exposed outside the display unit 2. The fixing unit F can have a U-shape or a W-shape structure, and the supporting part F11 connects the two adjacent first fixing parts F10.

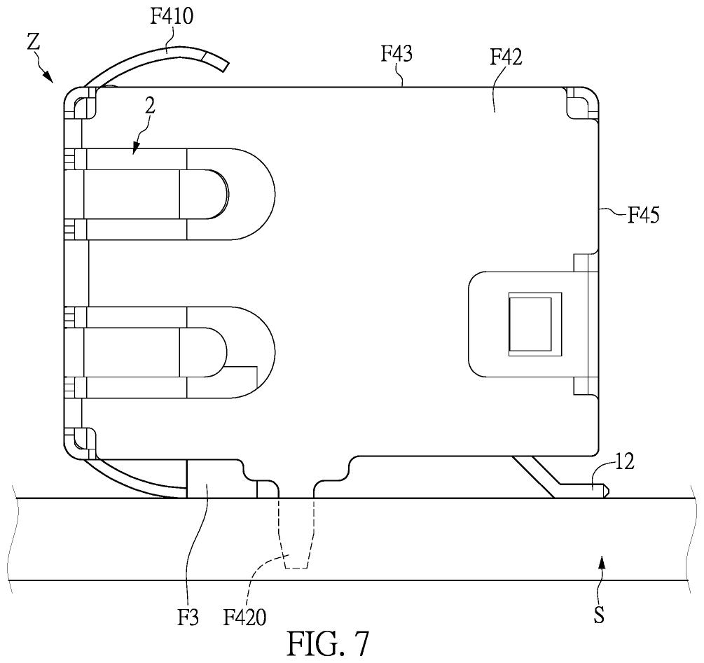

For example, as shown in FIG. 1, the U-shaped structure of the fixing unit F can be formed by connecting one supporting part F11 to the two adjacent first fixing parts F10. In addition, the supporting part F11 can be embedded in the display unit 2, and the two adjacent first fixing parts F10 are exposed outside the display unit 2. The first fixing part F10 can have a columnar structure. Accordingly, the fixing unit F can be inserted into the external substrate S through the first fixing part F10 to hold the display unit 2 upright on the external substrate S. That is, the display unit 2 is fixed to the external substrate S and is perpendicular to the external substrate S (also as shown in FIG. 7).

As shown in FIG. 2, the W-shaped structure of the fixing unit F can also be formed by connecting a plurality of the supporting parts F11 to the plurality of first fixing parts F10. For example, the two first fixing parts F10 are connected to the same supporting part F11 at their adjacent ends, and another end of each of the two first fixing parts F10 is connected to each of another two supporting parts F11, but is not limited thereto. Moreover, the supporting parts F 11 can also be embedded in the display unit 2, and the plurality of first fixing parts F10 are exposed outside the display unit 2. The first fixing part F10 can have a columnar structure. Accordingly, the fixing unit F can be adhered to the external substrate S through the first fixing part F10 in combination with solder paste or other adhesives, so as to hold the display unit 2 upright on the external substrate S.

Accordingly, the digital display Z of the present disclosure can not only be disposed on the external substrate S in an upright manner through the abovementioned technical solution, but can also be disposed on the external substrate S together with other electronic components by using a surface mount technology (SMT) process without the need for a separate SMT process.

In addition, the bottom of the display unit 2 protrudes outward to form at least one first positioning part 21. Accordingly, when the digital display Z of the present disclosure is fixed on the external substrate S through the fixing unit F, in addition to using the first positioning part 21 to achieve the function of limiting a distance between the display unit 2 and the external substrate S, the display unit 2 can also be firmly held by the first positioning part 21 abutting against the external substrate S, so that the display unit 2 can be firmly held upright on the external substrate S. With respect to the external substrate S, protrusion heights of the first positioning part 21, the first fixing part F10 of the fixing unit F, and the substrate of the light unit 1 are preferably equal, thereby providing a more stable supporting structure.

However, the aforementioned example is merely one of the feasible embodiments, and is not meant to limit the scope of the present disclosure.

### Second Embodiment

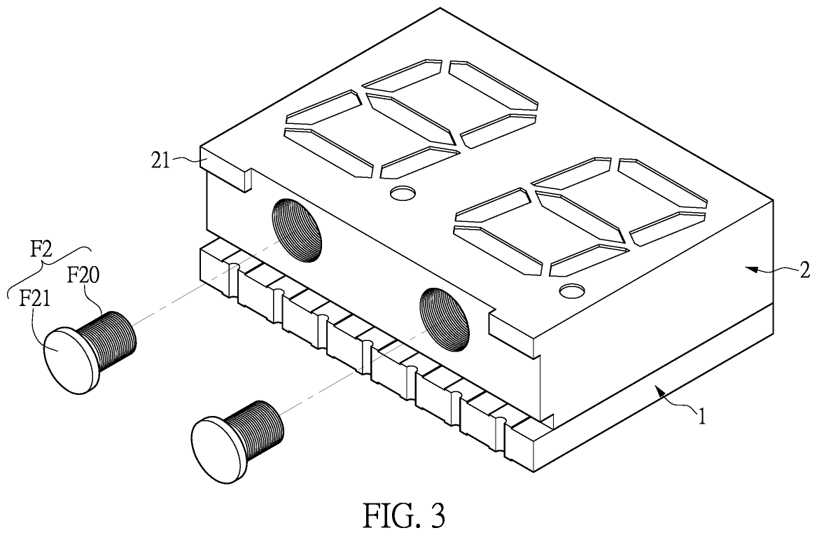

Referring to FIG. 3, which is to be read in conjunction with FIG. 1 and FIG. 2, a partly exploded view of a digital display according to a second embodiment of the present disclosure is shown. As shown in the figures, the digital display Z in the present embodiment is substantially similar to the digital display Z in the first embodiment described above, and will not be repeated herein. The difference between the present embodiment and the first embodiment described above is that in the present embodiment, the fixing unit F can include a plurality of supporting members F2. One end of each of the supporting members F2 is connected to the display unit 2, and the other end of each of the supporting members F2 is exposed outside the display unit 2.

For example, the fixing unit F of the present disclosure can include a plurality of supporting members F2. Each of the supporting members F2 has a main body part F20 and a second fixing part F21 connected to the main body part F20. The main body part F20 can be embedded in the display unit 2, and the second fixing part F21 can be exposed outside the display unit 2. The supporting member F2 can be similar to the structural design of a headpin, but is not limited thereto. Accordingly, the digital display Z in the present embodiment can be adhered to the external substrate S through the second fixing part F21 of each of the supporting members F2 in cooperation with solder paste or other adhesives, so as to hold the display unit 2 upright on the external substrate S. Moreover, the light unit 1 can also be electrically connected to the external substrate S.

It is worth noting that the plurality of supporting members F2 and the display unit 2 of the present disclosure can form a single, integral component (being made in the manner described in the first embodiment) or can be independent components. In an embodiment in which the plurality of supporting members F2 and the display unit 2 are independent components, the plurality of supporting members F2 can be engaged with each other by snap-fixing, screwing, or other joining methods.

Further, when the digital display Z of the present disclosure is fixed to the external substrate S by the second fixing part F21 of the fixing unit F, the display unit 2 can also be firmly held upright on the external substrate S by the first positioning part 21 of the display unit 2 abutting against the external substrate S.

However, the aforementioned example is merely one of the feasible embodiments, and is not meant to limit the scope of the present disclosure.

### Third Embodiment

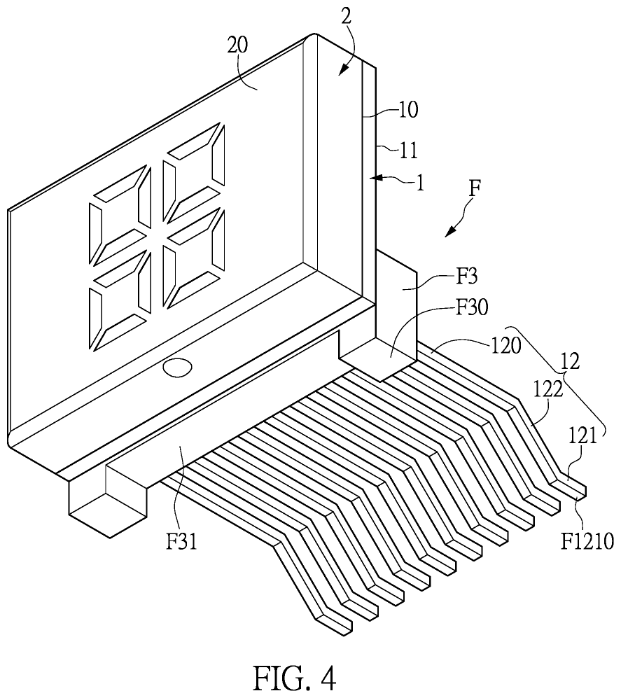

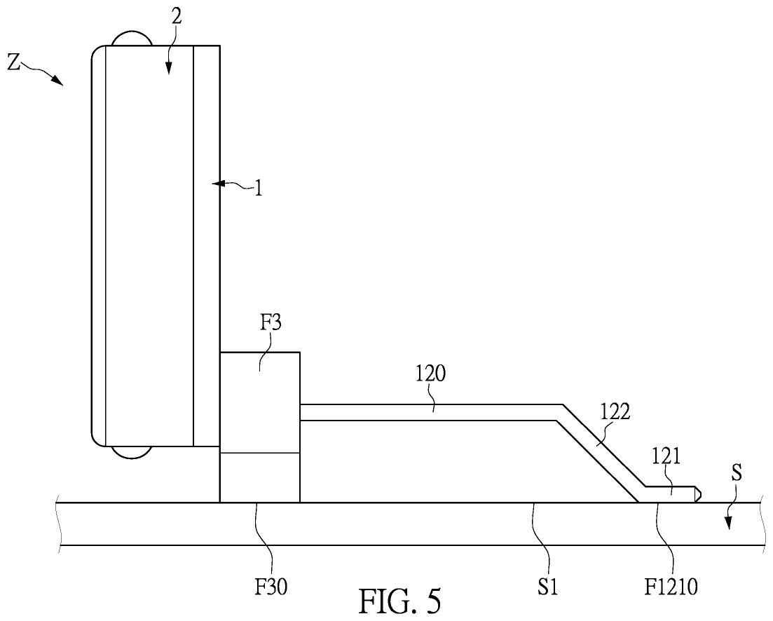

Referring to FIG. 4 and FIG. 5, which are to be read in conjunction with FIG. 1 to FIG. 3, a perspective view and a side view of a digital display according to a third embodiment of the present disclosure are shown, respectively. As shown in the figures, the digital display Z in the present embodiment is substantially similar to those in the embodiments described above, and will not be repeated herein. The difference between the present embodiment and the embodiments described above is that in the present embodiment, the light unit 1 has a rear 11 opposite to the front 10 and a plurality of terminals 12 correspondingly connected to the rear 11.

For example, as shown in FIG. 4 and FIG. 5, the light unit 1 in the present embodiment has the front 10 and the rear 11 opposite to the front 10, and the plurality of terminals 12 as a pin array are connected to the rear 11 of the light unit 1. Therefore, the light unit 1 can be electrically connected to the external substrate S through the plurality of terminals 12 (also as shown in FIG. 7).

Further, the fixing unit F can include a positioning member F3, which is connected to the rear 11 and corresponds to a bottom of the light unit 1. In addition, one end of each of the terminals 12 passes through the positioning member F3 at an equal interval and on the same horizontal plane, and is connected to the rear 11. The one end and another end of each of the terminals 12 are arranged in a staggered manner and parallel to each other. There can be ten terminals 12, but is not limited thereto.

For example, as shown in FIG. 4, the fixing unit F of the present disclosure can include the positioning member F3, which may have an inverted U-shaped structure. The positioning member F3 has a bottom surface F30 that is perpendicular to and away from the rear 11, and a concave part F31 is formed by an inward depression of the bottom surface F30. Each of the terminals 12 has a front end part 120, a rear end part 121 and a mid-end part 122. The mid-end part 122 is correspondingly connected to the front end part 120 and the rear end part 121. The front end part 120 passes through the positioning member F3 and is connected to the rear 11. The front end part 120 and the rear end part 121 are arranged in a staggered manner and parallel to each other. The mid-end part 122 is inclined relative to the front end part 120 and the rear end part 121. In addition, a contact 1210 of the rear end part 121 in contact with the external substrate S is parallel to and coplanar with the bottom surface F30.

Accordingly, when the digital display Z is disposed on the external substrate S, it can be connected to the external substrate S through the bottom surface F30 of the positioning member F3 and the rear end part 121 of the terminal 12 of the light unit 1, so that the display unit 2 can be held upright on the external substrate S. The bottom surface F30 and the rear end part 121 can be fixed on the external substrate S by using solder paste or other adhesives.

However, the aforementioned example is merely one of the feasible embodiments, and is not meant to limit the scope of the present disclosure.

### Fourth Embodiment

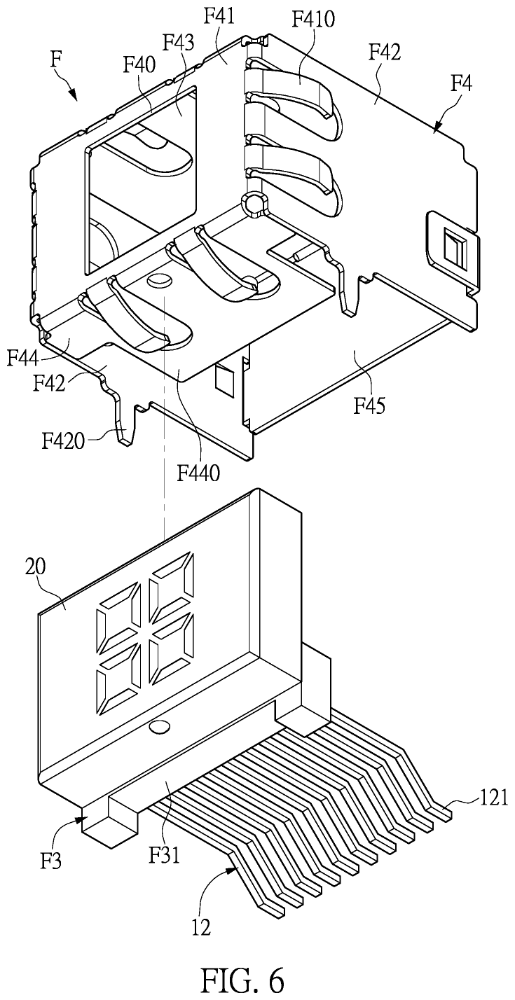

Referring to FIG. 6 and FIG. 7, which are to be read in conjunction with FIG. 1 to FIG. 5, an exploded view and a side view of a digital display according to a fourth embodiment of the present disclosure are shown, respectively. As shown in the figures, the digital display Z in the present embodiment is substantially similar to the digital display Z in the third embodiment described above, and will not be repeated herein. The difference between the present embodiment and the third embodiment described above is that in the present embodiment, the fixing unit F includes a shield member F4 of a window F40. The light unit 1 and the display unit 2 are arranged inside the shield member F4, and the display surface 20 of the display unit 2 corresponds to the window F40.

For example, as shown in FIG. 5 and FIG. 6, the fixing unit F of the present disclosure can include the shield member F4, which can be hollow and have the window F40 communicating between the exterior and the interior on its front side surface. The interior of the shield member F4 can accommodate the light unit 1, the display unit 2 and the positioning member F3, and the window F40 is adjacent to and corresponds to the display surface 20. Accordingly, the digital display Z of the present disclosure can be shielded from an external electromagnetic interference (EMI) through the shield member F4.

Further, the shield member F4 can include a front part F41, a plurality of side parts F42, an upper part F43, a lower part F44 and a rear part F45. The front part F41 has the window F40, the front part F41 is arranged opposite to the rear part F45, each end of the plurality of side parts F42 and the upper part F43 is correspondingly connected to front part F41 and the rear part F45, and one side of each of the side parts F42 corresponding to the lower part F44 protrudes outward to form at least one third fixing part F420. One end of the lower part F44 is connected to the front part F41, and at least one matching part F440 is formed by the extension toward the rear part F45 on another end of the lower part F44. The one of the ends of the plurality of side parts F42, the upper part F43 and the lower part F44 connected to the front part F41 correspondingly include at least one elastic element F410.

For example, the shield member F4 of the present disclosure can include the front part F41, the plurality of side parts F42, the upper part F43, the lower part F44 and the rear part F45, but is not limited thereto. The plurality of side parts F42, the upper part F43 and the lower part F44 are correspondingly connected to the front part F41, and the upper part F43 is connected to the rear part F45. The plurality of side parts F42 correspond to and are parallel to each other, the upper part F43 and the lower part F44 correspond to and are parallel to each other, and the front part F41 and the rear part F45 correspond to and are parallel to each other, but is not limited thereto.

Accordingly, the digital display Z of the present disclosure can cover the light unit 1, the display unit 2 and the positioning member F3 through the shield member F, and also uses the matching part F440 of the lower part F44 to engage with the concave part F31 of the positioning member F3, thereby firmly fixing the light unit 1, the display unit 2 and the positioning member F3 inside the shield member F4. The bottom surface F30 of the positioning member F3 is exposed outside the lower part F44 of the shield member F4. Then, when being disposed on the external substrate S, the digital display Z is erected on a surface Si of the external substrate S through the bottom surface F30 of the positioning member F3 and the rear end part 121 of the terminals. Further, the third fixing part F420 of each of the side parts F42 can be inserted into the external substrate S to firmly hold the display unit 2 upright on the external substrate S. In addition, the digital display Z of the present disclosure can be engaged with an external object, such as a plate, through the elastic element F410 of the shield member F4, so as to fix a side with the display surface 20 of the digital display Z to the external object.

However, the aforementioned example is merely one of the feasible embodiments, and is not meant to limit the scope of the present disclosure.

### Fifth Embodiment

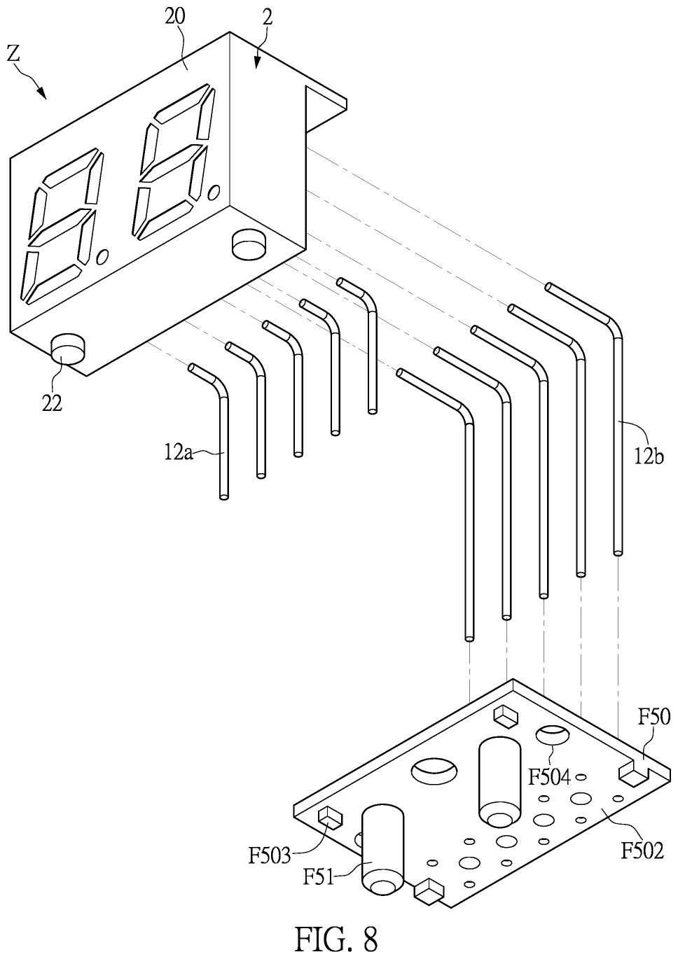

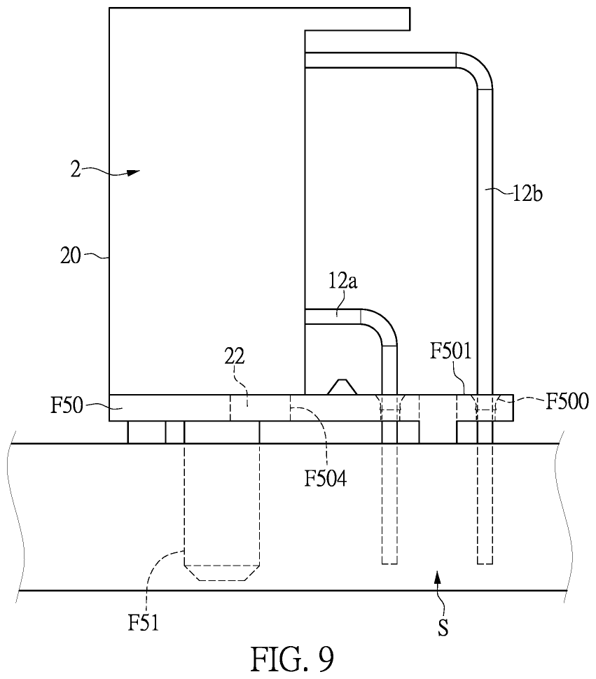

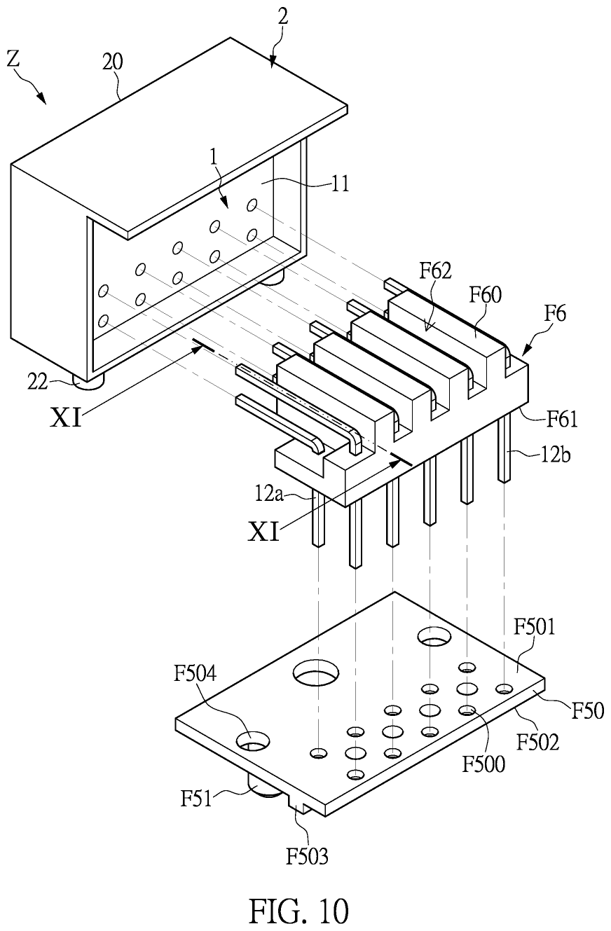

Referring to FIG. 8 to FIG. 11, which are to be read in conjunction with FIG. 1 to FIG. 7, a side view and a second exploded view of a digital display according to a fifth embodiment of the present disclosure, as well as a sectional schematic view of part XI-XI in FIG. 10 are shown, respectively. As shown in the figures, the digital display Z in the present embodiment is substantially similar to the digital display Z in the third embodiment described above, and will not be repeated herein. The difference between the present embodiment and the third embodiment described above is that in the present embodiment, the fixing unit F includes a base F50 connected to the display unit 2 and a plurality of fixing members F51 connected to the base F50. The base F50 has a plurality of first through holes F500, each of the plurality of terminals 12 has an L-shaped structure, and each of the plurality of terminals 12 passes through the corresponding first through holes F500. One end of each of the terminals 12 is connected to the display surface 11, and the other end of each of the terminals 12 is connected the external substrate S. As shown in FIG. 8 to FIG. 10, the plurality of terminals 12 can be arranged in upper and lower rows and be connected to the rear 11, and the plurality of terminals 12 in each row are arranged on the same horizontal plane and at an equal interval.

For example, as shown in FIG. 8 to FIG. 10, the fixing unit F of the present disclosure can include the base F50 and the plurality of fixing members F51 in the present embodiment. The base F50 has an upper surface F501 and a lower surface F502 corresponding to each other, and each of the first through holes F500 is spatially communicated with the upper surface F501 and the lower surface F502. The light unit 1 and the display unit 2 can be disposed on the upper surface F501 of the base F50. Each of the terminals 12 of the light unit 1 passes through one of the first through holes F500, and the fixing member F51 can be connected to the lower surface F502 of the base F50.

Accordingly, when the digital display Z is disposed on the external substrate S, the digital display Z can be inserted into the external substrate S through the plurality of fixing members F51 to hold the display unit 2 upright on the external substrate S. In addition, the plurality of terminals 12 can also be used to connect to the external substrate S, such that the digital display Z is electrically connected to the external substrate S (also shown in FIG. 7).

Further, the lower surface F502 of the base F50 can protrude outward to form a plurality of limiting parts F503. Therefore, the plurality of limiting parts F503 can limit a distance between the base F50 and the external substrate S when the plurality of fixing members F51 are inserted into the external substrate S, and also firmly hold the base F50 by abutting against the external substrate S after the plurality of fixing members F51 are inserted into the external substrate S. In this way, the display unit 2 can be firmly held upright on the external substrate S by the base F50.

Still further, the base F50 can have at least one second through hole F504, and at least one positioning part 22 is formed by a protrusion outward on one side of the display unit 2 corresponding to the base F50.

For example, the base F50 of the present disclosure can have at least one second through hole F504 corresponding to the display unit 2, and a bottom surface of the display 2 has a second positioning part 22 corresponding to the second through hole F504. Therefore, when the display unit 2 is disposed on the base F50, the display unit 2 can be engaged in the second through hole F504 through the second positioning part 22 to be accurately positioned on the base F50, so as to prevent a shift in position.

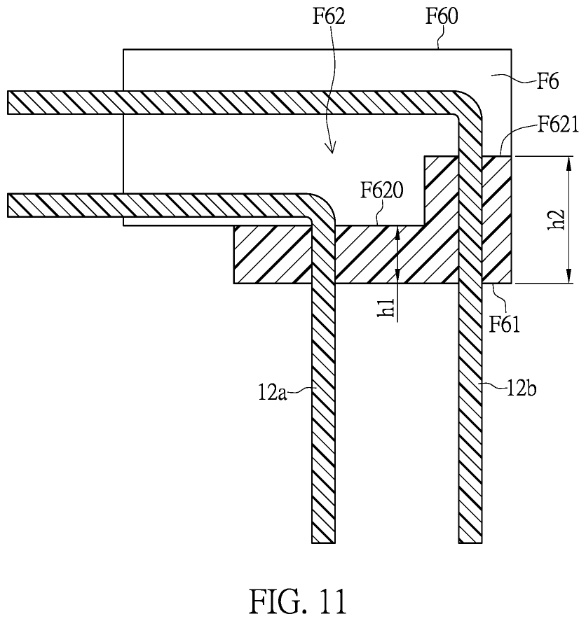

Still further, as shown in FIG. 10 and FIG. 11, the fixing unit F of the present disclosure can further include a holder F6 disposed on the base F50. The holder F6 has a top surface F60 and a bottom surface F61. In addition, the holder F6 further has a plurality of grooves F62 arranged at intervals, and each of the grooves F62 has a first surface F620 and a second surface F621 that are arranged adjacently and in a staggered mariner. That is, a ladder structure is formed in each of the grooves F62. A distance h1 between the first surface F620 and the bottom surface F61 is smaller than a distance h2 between the second surface F621 and the bottom surface F61. For example, the holder F6 can also be disposed on the upper surface F501 of the base F50, and the holder F6 has the plurality of grooves F62 that can have the plurality of terminals 12a and 12b disposed therein. One part of the terminals 12a passes through the first surface F620, and another part of the terminals 12b passes through the second surface F621. Accordingly, the holder F6 is disposed on the base F50 to firmly fix the plurality of terminals 12a and 12b. In other words, the plurality of terminals 12a and 12b have a two-row structure, and the holder F6 has accommodation spaces for the terminals 12a disposed on the first row and for the terminals 12b disposed on the second row, correspondingly. Moreover, the grooves F62 which are arranged at intervals act as limit slots, so that each set of the terminals 12a and 12b are stably installed in the grooves F62 of the holder F6. Each of the grooves F62 accommodates a set of the terminals 12a and 12b. By using a ladder structure with a height difference, the terminals 12a of the first row and the terminals 12b of the second row are installed on the first surface F620 and the second surface F621 of the groove F62, respectively. In this way, there is a vertical height difference (i.e., obtained by subtracting the distance h2 and the distance h1) between each set of the terminals 12a and 12b, and a short circuit caused by a contact between middle parts of the terminals 12a of the first row and the terminals 12b of the second row can be prevented from damaging the circuit board.

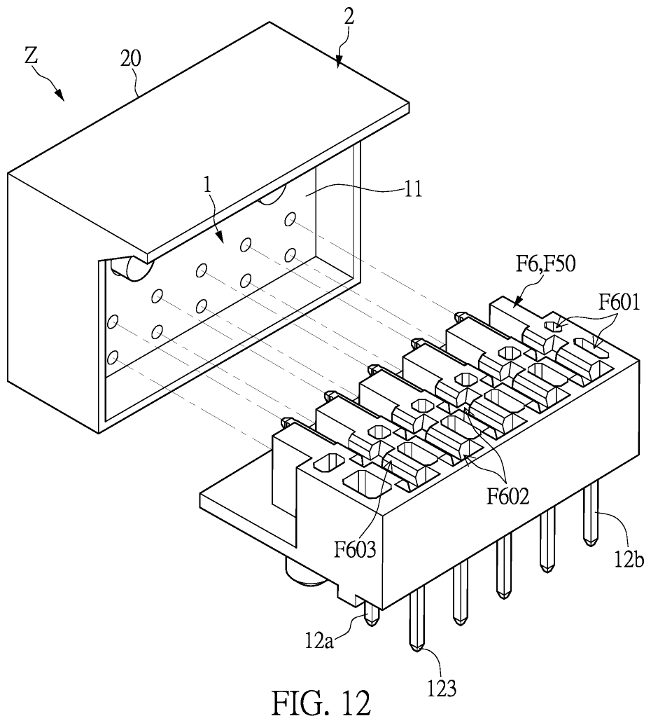

In addition, the terminals 12a and 12b can be a pair array with round pins or square pins, but is not limited thereto. As shown in FIG. 12, each end of each of the terminals 12a and 12b has a chamfer 123, and the chamfer 123 can have any suitable shape (e.g., chamfer or round). The holder F6 has a plurality of pair of pin holes corresponding to the plurality of the terminals 12a and 12b, wherein the pin holes can be round holes or square holes, complementary to the shape of the pins.

In addition, the base 50 and the holder F6 of the present disclosure can be a single, integral component, as shown in FIG. 12. The holder F6 has a plurality of accommodation spaces (i.e., the grooves F62) for the plurality of terminals 12a and 12b, and the plurality of terminals 12a and 12b have the two-row structure. One end of each of the plurality of terminals 12a and 12b is connected to the rear 11, and another end of each of the plurality of terminals 12a and 12b is connected to the external substrate S. In the present embodiment, the base 50 and the holder F6 that are formed as a single component have a pair of slug holes F601 passing through the base 50 and the holder F6 that are formed as a single component, and the pair of slug holes F601 can be used to reduce a shrinkage of the base 50 and the holder F6. In addition, the holder F6 can have at least one avoiding slot F602 and at least one chamfered edge F603 on the top surface of the holder F6 adjacent to the accommodation spaces (i.e., the grooves F62) for the plurality of terminals 12a and 12b. The avoiding slot F602 is adopted for accommodating at least one jig, and the at least one chamfered edge F603 is adopted for easily disposing the plurality of terminals 12a and 12b in the accommodation spaces. In the present embodiment, there are two avoiding slots F602 corresponding to each of the accommodation space and at least one pair of the chamfered edges F603 are formed on two of the top surfaces F60 that are opposite to each other. Moreover, the chamfered edge F603 can have any suitable shape (e.g., chamfer or round). It is worth noting that the base F50 and the display unit 2 of the present disclosure are not limited to the above embodiments. In another embodiment, a groove can also be formed by an inward depression on the bottom surface of the display unit 2, while a protrusion corresponding to the groove can be formed by the base F50 protruding outward.

However, the aforementioned example is merely one of the feasible embodiments, and is not meant to limit the scope of the present disclosure.

### Beneficial Effects of the Embodiments

In conclusion, the digital display Z of the present disclosure can not only be disposed on the external substrate S in an upright manner through the abovementioned technical solution, where the fixing unit F is used to hold the display unit 2 upright on the external substrate S, but can also be disposed on the external substrate S together with other electronic components by using a surface mount technology (SMT) process without the need for a separate SMT process.

Further, through the technical solution described above, the display unit 2 and the fixing unit F in the digital display Z of the present disclosure can be a single, integral component or can be independent components, and the display unit 2 can be fixed on the external substrate S in an upright manner by using the fixing unit F. In addition, the digital display Z of the present disclosure can be shielded from an external electromagnetic interference (EMI) through the shield member F4.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A digital display, comprising:
a light unit having a light emitting surface;
a display unit having a display surface corresponding to the light emitting surface; and
a fixing unit being used to hold the display unit upright on an external substrate.

2. The digital display according to claim 1, wherein the display unit and the fixing unit are formed as an integrated component.

3. The digital display according to claim 2, wherein the fixing unit includes a plurality of fixing parts and at least one supporting part correspondingly embedded in the display unit, the plurality of fixing parts being exposed outside the display unit.

4. The digital display according to claim 3, wherein the fixing unit has a U-shaped or a W-shaped structure, and the supporting part connects the two adjacent fixing parts.

5. The digital display according to claim 2, wherein the fixing unit includes a plurality of supporting members, one end of each of the supporting members is connected to the display unit, and another end of each of the supporting members is exposed outside the display unit.

6. The digital display according to claim 1, wherein the light unit has a front as the light emitting surface and a rear opposite to the front and a plurality of terminals connected to the rear.

7. The digital display according to claim 6, wherein the fixing unit includes a positioning member, and the positioning member is connected to the rear.

8. The digital display according to claim 6, wherein one end of each of the terminals passes through the positioning member and is connected to the rear, and the one end and another end of each of the terminals are arranged in a staggered manner and parallel to each other.

9. The digital display according to claim 7, wherein the fixing unit has a bottom surface adjacent to the external substrate; wherein each of the terminals has a front end part, a rear end part and a mid-end part, the mid-end part is connected to the front end part and the rear end part, the front end part passes through the positioning member and is connected to the rear of the light unit, the front end part and the rear end part are arranged in a staggered manner and parallel to each other, and the mid-end part is inclined relative to the front end part and the rear end part; wherein a contact where the rear end part is in contact with the external substrate is parallel to and coplanar with the bottom surface.

10. The digital display according to claim 7, wherein the fixing unit includes a shield member having a window; wherein the light unit and the display unit are arranged inside the shield member, and the display surface of the display unit corresponds to the window; wherein the shield member includes a front part and a plurality of side parts, the front part has the window, the plurality of side parts are connected to the front part, and each of the side parts protrudes downward to form at least one third fixing part.

11. The digital display according to claim 10, wherein the shield member further includes an upper part, a lower part and a rear part, the front part is arranged opposite to the rear part, two ends of the plurality of side parts and the upper part are correspondingly connected to the front part and the rear part, one end of the lower part is connected to the front part, and another end of the lower part extends towards the rear part to form at least one matching part; wherein one end of the plurality of side parts, one end of the upper part and one end of the lower part that are each connected to the front part include at least one elastic element.

12. The digital display according to claim 6, wherein the fixing unit includes a base connected to the display unit and a plurality of fixing members connected to the base; wherein the base has a plurality of first through holes, the plurality of terminals are L-shaped structures that are arranged in two rows, each of the plurality of terminals passes through the corresponding first through hole, one end of each of the terminals is connected to the rear, and another end of each of the terminals is connected to the external substrate.

13. The digital display according to claim 7, wherein the fixing unit further includes a holder disposed on the base, the holder has a top surface and a bottom surface, and the holder further has a plurality of grooves arranged at intervals; wherein each of the grooves has a first surface and a second surface that are arranged adjacent to each other in a staggered manner; wherein a distance between the first surface and the bottom surface is smaller than a distance between the second surface and the bottom surface.

14. The digital display according to claim 13, wherein the fixing unit further has at least one slug hole passing through the holder and the base.

15. The digital display according to claim 13, wherein the fixing unit further has at least one avoiding slot on the top surface of the holder adjacent to the plurality of grooves.

16. The digital display according to claim 1, wherein one side of the display unit corresponding to the external substrate or the base protrudes to form at least one positioning part.

17. The digital display according to claim 1, wherein the display unit further includes a reflective member and a print tape pasted onto the reflective member, and the print tape has a plurality of light transmissive segments for displaying digits, text, symbols and graphics.
